(19) United States
(12) Patent Application Publication
(10) Pub. No.: US 2021/0005426 A1
(43) Pub. Date: Jan. 7, 2021

(54) APPARATUS AND METHOD FOR TREATING SUBSTRATE

(71) Applicant: SEMES CO., LTD., Cheonan-si (KR)

(72) Inventor: Dongha LEE, Hwaseong-si (KR)

(73) Assignee: SEMES CO., LTD., Cheonan-si (KR)

(21) Appl. No.: 16/919,564

(22) Filed: Jul. 2, 2020

(30) Foreign Application Priority Data
Jul. 3, 2019 (KR) 10-2019-0080332

(51) Int. Cl. H01J 37/32; H01L 21/67; H01L 21/683; H01L 21/3065; H01L 21/66

(52) U.S. Cl. CPC H01J 37/32082; H01L 21/67069; H01L 21/67103; H01L 21/67253; H01J 2237/334; H01L 21/3065; H01L 22/26; H01J 37/32724; H01J 37/3244; H01L 21/6833

(57) ABSTRACT

An apparatus for treating a substrate includes a chamber having a treatment space therein, a support unit that supports the substrate in the treatment space, a gas supply unit that supplies, into the treatment space, a process gas used to treat the substrate, a plasma source that generates plasma by exciting the process gas supplied into the treatment space, heaters that heat the support unit for different regions of the substrate, a heater power supply that applies powers to the heaters, a plurality of heater cables that deliver the powers to the heaters, and variable capacitors configured be grounded, the variable capacitors being connected to the plurality of heater cables, respectively.

### CROSS-REFERENCE TO RELATED APPLICATIONS

A claim for priority under 35 U.S.C. § 119 is made to Korean Patent Application No. 10-2019-0080332 filed on Jul. 3, 2019, in the Korean Intellectual Property Office, the entire contents of which are hereby incorporated by reference.

### BACKGROUND

Embodiments of the inventive concept described herein relate to an apparatus and method for treating a substrate, and more particularly, relate to a substrate treating apparatus including variable capacitors that are configured to be grounded and are connected to cables.

To manufacture semiconductor elements, desired patterns are formed on a substrate by performing various processes such as photolithography, etching, ashing, ion implantation, thin-film deposition, cleaning, and the like. Among these processes, the etching process is a process of removing a selected region of a film formed on the substrate. The etching process is classified into a wet etching process and a dry etching process. An etching apparatus using plasma is used for the dry etching process. In general, to generate plasma, an electromagnetic field is formed in the interior space of a chamber. The electromagnetic field excites a process gas in the chamber into plasma. The plasma refers to an ionized gaseous state of matter containing ions, electrons, and radicals. The plasma is generated by very high temperature, a strong electric field, or an RF electromagnetic field. A semiconductor element manufacturing process performs an etching process using plasma. The etching process is performed by collision of ion particles contained in the plasma with a substrate.

A heat treatment process may be performed in a substrate treating apparatus. When a substrate is placed on a heating plate, the corresponding substrate is subjected to heat treatment through heating members provided in the heating plate. The heating members may be disposed in a plurality of heating zones for heating different regions of the substrate. The heating members may be connected with a power supply through cables.

Depending on grounded or floating states of the cables connecting the heating members and the power supply, management issues such as an etch rate and a plasma voltage trend may arise, and a process result such as a CD deviation may be changed. Accordingly, a substrate treating apparatus capable of controlling grounded or floating states of cables is required.

### SUMMARY

Embodiments of the inventive concept provide a substrate treating apparatus for improving and controlling plasma voltages in desired directions by using variable capacitors that are configured to be grounded and are connected to ends of cables.

The technical problems to be solved by the inventive concept are not limited to the aforementioned problems. Any other technical problems not mentioned herein will be clearly understood from the following description by those skilled in the art to which the inventive concept pertains.

According to an exemplary embodiment, an apparatus for treating a substrate includes a chamber having a treatment space therein, a support unit that supports the substrate in the treatment space, a gas supply unit that supplies, into the treatment space, a process gas used to treat the substrate, a plasma source that generates plasma by exciting the process gas supplied into the treatment space, heaters that heat the support unit for different regions of the substrate, a heater power supply that applies powers to the heaters, a plurality of heater cables that deliver the powers to the heaters, and variable capacitors configured be grounded, the variable capacitors being connected to the plurality of heater cables, respectively.

The apparatus may further include a filter that passes the powers through the plurality of heater cables and interrupts introduction of RF power into the heater power supply, and the plurality of heater cables may be connected between the filter and the heaters.

The variable capacitors configured to be grounded may be connected to input terminals of the filter.

The filter may include a plurality of terminals, and the variable capacitors configured to be grounded may be connected to ground terminals among the plurality of terminals.

The variable capacitors configured to be grounded may operate in one of a ground state or a floating state.

In the floating state, plasma voltages applied to the respective different regions of the substrate may be controlled by adjusting a distance between electrodes of each of the variable capacitors.

The ground state may be adjusted by turning on/off a ground switch connected in parallel with each of the variable capacitors.

The apparatus may adjust magnitudes of power losses for the respective different regions of the substrate by adjusting the variable capacitors configured to be grounded.

The apparatus may adjust plasma voltages applied to the respective different regions of the substrate by adjusting the variable capacitors configured to be grounded.

According to an exemplary embodiment, a substrate treating method for controlling plasmas by adjusting powers applied to respective different regions of a substrate includes controlling the plasmas applied to the respective different regions of the substrate by adjusting variable capacitors included in ends of heater cables that connect the substrate and a heater power supply that applies the powers to the different regions of the substrate.

The variable capacitors may be components connected so as to be grounded.

The variable capacitors may operate in one of a ground state or a floating state.

In the floating state, plasma voltages applied to the respective different regions of the substrate may be controlled by adjusting a distance between electrodes of each of the variable capacitors.

The ground state may be adjusted by turning on/off a ground switch connected in parallel with each of the variable capacitors.

According to an exemplary embodiment, a substrate treating method for controlling plasmas by adjusting powers applied to respective different regions of a substrate includes a step of measuring plasma voltages for the respective different regions of the substrate, a step of determining whether there is an imbalance in plasma between the different regions of the substrate, a step of selecting a region to be adjusted among the different regions of the substrate, and a step of adjusting plasma voltages applied to the respective different regions of the substrate by adjusting variable capacitors that are configured to be grounded and are included in cables that connect the substrate and a power supply that applies the powers to the different regions of the substrate.

In the step of adjusting the plasma voltages applied to the respective different regions of the substrate, the variable capacitors configured to be grounded may be controlled to operate in one of a ground state or a floating state.

In the floating state, the plasma voltages applied to the respective different regions of the substrate may be controlled by adjusting a distance between electrodes of each of the variable capacitors.

The ground state may be adjusted by turning on/off a ground switch connected in parallel with each of the variable capacitors.

Power losses for the respective different regions of the substrate may be adjusted by adjusting the variable capacitors configured to be grounded.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a substrate treating apparatus according to an embodiment of the inventive concept;

FIG. 2 is a plan view illustrating heaters, heater cables, variable capacitors configured to be grounded, a filter, and a heater power supply constituting the substrate treating apparatus according to an embodiment of the inventive concept;

FIGS. 3A to 3C are views illustrating configurations of a variable capacitor connected with a filter and configured to be grounded according to an embodiment of the inventive concept;

FIG. 4 is a view illustrating connection of terminals of a filter and variable capacitors configured to be grounded, according to the inventive concept;

FIG. 5 is a flowchart illustrating a substrate treating method of the inventive concept; and

FIG. 6 is a view illustrating a difference in etch rate between an existing substrate treating apparatus and a substrate treating apparatus according to the inventive concept.

### DETAILED DESCRIPTION

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that the inventive concept will be thorough and complete, and will fully convey the scope of the inventive concept to those skilled in the art. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

Hereinafter, a substrate treating apparatus for etching a substrate by generating plasma in an inductively coupled plasma (ICP) type will be described. Without being limited thereto, however, the inventive concept may be applicable to various types of apparatuses for treating a substrate by generating plasma in a capacitively coupled plasma (CCP) type or a remote plasma type.

In embodiments of the inventive concept, an electrostatic chuck exemplifies a support unit. Without being limited thereto, however, the support unit may support a substrate by mechanical clamping, or may support a substrate by vacuum pressure.

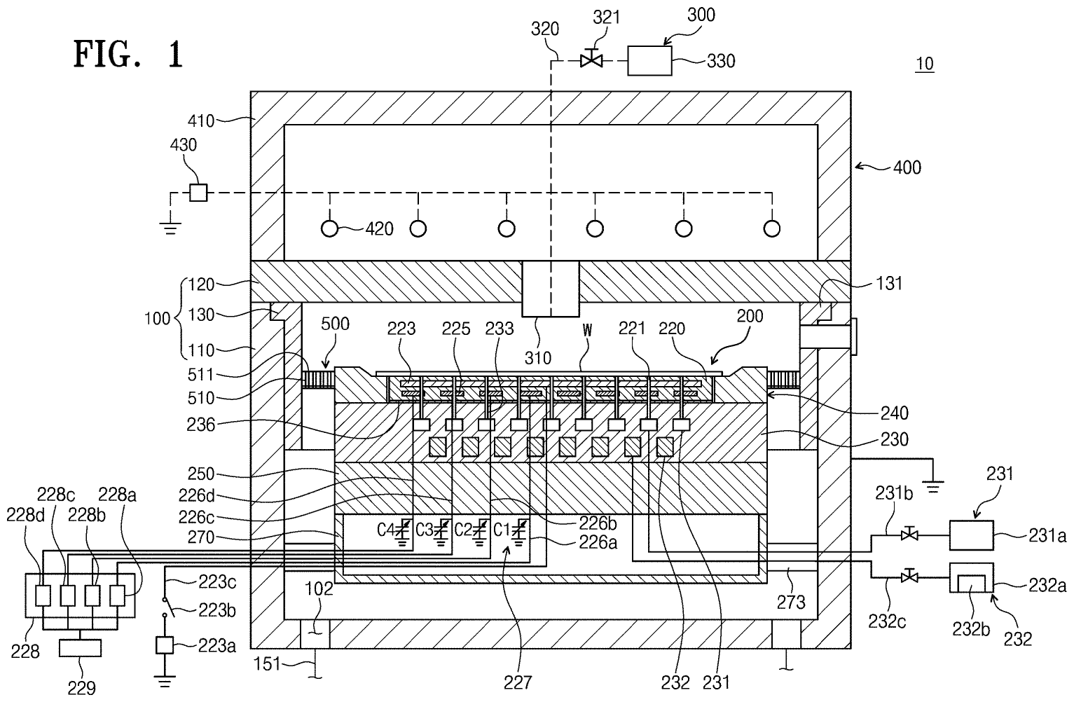

FIG. 1 is a sectional view illustrating a substrate treating apparatus according to an embodiment of the inventive concept. Referring to FIG. 1, the substrate treating apparatus 10 treats a substrate W using plasma. For example, the substrate treating apparatus 10 may perform an etching process on the substrate W. The substrate processing apparatus 10 includes a chamber 100, a support unit 200, a gas supply unit 300, a plasma source 400, and an exhaust unit 500.

The chamber 100 has a treatment space therein in which the substrate W is treated. The chamber 100 includes a housing 110, a cover 120, and a liner 130.

The housing 110 has a space therein, which is open at the top. The interior space of the housing 110 serves as a treatment space in which a substrate treating process is performed. The housing 110 is formed of a metallic material. The housing 110 may be formed of an aluminum material. The housing 110 may be grounded. The housing 110 has an exhaust hole 102 formed in the bottom thereof. The exhaust hole 102 is connected with an exhaust line 151. Reaction byproducts generated in the substrate treating process and gases staying in the interior space of the housing 110 may be released to the outside through the exhaust line 151. The pressure in the housing 110 is reduced to a predetermined pressure by the exhaust process.

The cover 120 covers the open top of the housing 110. The sealing cover 120 has a plate shape and seals the interior space of the housing 110. The cover 120 may include a dielectric substance window.

The liner 130 is provided inside the housing 110. The liner 130 has an interior space that is open at the top and the bottom. The liner 130 may have a cylindrical shape. The liner 130 may have a radius corresponding to an inner surface of the housing 110. The liner 130 is provided along the inner surface of the housing 110. The liner 130 has a support ring 131 formed on an upper end thereof. The support ring 131 is implemented with a plate in a ring shape and protrudes outward from the liner 130 along the periphery of the liner 130. The support ring 131 is placed on an upper end of the housing 110 and supports the liner 130. The liner 130 may be formed of the same material as that of the housing 110. The liner 130 may be formed of an aluminum material. The liner 130 protects the inner surface of the housing 110. For example, arc discharge may occur in the chamber 100 in a process in which a process gas is excited. The arc discharge causes damage to surrounding devices. The liner 130 protects the inner surface of the housing 110, thereby preventing damage to the inner surface of the housing 110 by the arc discharge. Furthermore, the liner 130 prevents reaction by-products generated during the substrate treating process from being deposited on an inner wall of the housing 110. The liner 130 is inexpensive and is easy to replace, compared with the housing 110. Therefore, in a case where the liner 130 is damaged by the arc discharge, an operator may replace the liner 130 with a new one.

The support unit 200 supports the substrate W in the treatment space of the chamber 100. For example, the support unit 200 is disposed in the housing 110. The support unit 200 supports the substrate W. The support unit 200 may be implemented with an electrostatic chuck that clamps the substrate W using an electrostatic force. Alternatively, the support unit 200 may support the substrate W in various manners such as mechanical clamping. Hereinafter, it will be exemplified that the support unit 200 is implemented with an electrostatic chuck.

The support unit 200 includes a support plate 220, an electrostatic electrode 223, a fluid-channel-formed plate 230, a focus ring 240, an insulating plate 250, and a lower cover 270. In the chamber 100, the support unit 200 may be spaced apart upward from the bottom of the housing 110.

The support plate 220 is located at the top of the support unit 200. The support plate 220 is formed of a dielectric substance in a circular plate shape. The substrate W is placed on an upper surface of the support plate 220. The support plate 220 has a first supply passage 221 formed therein. The first supply passage 221 is used as a passage through which a heat transfer gas is supplied to a lower surface of the substrate W.

The electrostatic electrode 223 is embedded in the support plate 220. The electrostatic electrode 223 is electrically connected with a first lower power supply 223a. An electrostatic force acts between the electrostatic electrode 223 and the substrate W due to electric current applied to the electrostatic electrode 223, and the substrate W is clamped to the support plate 220 by the electrostatic force.

The fluid-channel-formed plate 230 is located under the support plate 220. A lower surface of the support plate 220 and an upper surface of the fluid-channel-formed plate 230 may be bonded together by an adhesive 236. The fluid-channel-formed plate 230 has a first circulation passage 231, a second circulation passage 232, and a second supply passage 233 formed therein. The first circulation passage 231 serves as a passage through which the heat transfer gas circulates. The second circulation passage 232 serves as a passage through which a cooling fluid circulates. The second supply passage 233 connects the first circulation passage 231 and the first supply passage 221. The first circulation passage 231 serves as a passage through which the heat transfer gas circulates. The first circulation passage 231 may be formed in a spiral shape inside the fluid-channel-formed plate 230. Alternatively, the first circulation passage 231 may be implemented with ring-shaped passages that have different radii and that are concentric with one another. The first circulation passages 231 may be connected together. The first circulation passages 231 are formed at the same height.

The first circulation passages 231 are connected with a heat transfer medium reservoir 231a through a heat transfer medium supply line 231b. The heat transfer medium reservoir 231a has a heat transfer medium stored therein. The heat transfer medium includes an inert gas. The heat transfer medium may include a helium (He) gas. The helium gas is supplied into the first circulation passages 231 through the heat transfer medium supply line 231b. The helium gas sequentially passes through the second supply passage 233 and the first supply passage 221 and is supplied to the lower surface of the substrate W. The helium gas serves as a medium that helps heat exchange between the substrate W and the support plate 220. Accordingly, the overall temperature of the substrate W is uniformly maintained.

The second circulation passage 232 is connected with a cooling fluid reservoir 232a through a cooling fluid supply line 232c. The cooling fluid reservoir 232a has a cooling fluid stored therein. The cooling fluid reservoir 232a may include a cooler 232b therein. The cooler 232b cools the cooling fluid to a predetermined temperature. Alternatively, the cooler 232b may be installed on the cooling fluid supply line 232c. The cooling fluid supplied to the second circulation passage 232 through the cooling fluid supply line 232c cools the fluid-channel-formed plate 230 while circulating along the second circulation passage 232. The fluid-channel-formed plate 230, while being cooled, cools the support plate 220 and the substrate W together to maintain the substrate W at a predetermined temperature. For the reason mentioned above, the temperature below the focus ring 240 is generally lower than the temperature above the focus ring 240.

The focus ring 240 is disposed on an edge region of the support unit 200. The focus ring 240 has a ring shape and surrounds the support plate 220. For example, the focus ring 240 is disposed around the support plate 220 to support an outer region of the substrate W.

The insulating plate 250 is located under the fluid-channel-formed plate 230. The insulating plate 250 is formed of an insulating material and electrically insulates the fluid-channel-formed plate 230 and the lower cover 270. The lower cover 270 is located at the bottom of the support unit 200. The lower cover 270 is located to be spaced apart upward from the bottom of the housing 110. The lower cover 270 has a space formed therein, which is open at the top. The open top of the lower cover 270 is covered with the insulating plate 250. Accordingly, the outer diameter of the cross-section of the lower cover 270 may be the same as the outer diameter of the insulating plate 250. The lower cover 270 may have, in the interior space thereof, lift pins that receive the substrate W from an external transfer member and place the substrate W on the support plate 220.

The lower cover 270 has a connecting member 273. The connecting member 273 connects an outer surface of the lower cover 270 and the inner wall of the housing 110. A plurality of connecting members 273 may be provided on the outer surface of the lower cover 270 at predetermined intervals. The connecting members 273 support the support unit 200 in the chamber 100. Furthermore, the connecting members 273 are connected to the inner wall of the housing 110 to allow the lower cover 270 to be electrically grounded.

A first power line 223c connected with the first lower power supply 223a, the heat transfer medium supply line 231b connected with the heat transfer medium reservoir 231a, and the cooling fluid supply line 232c connected with the cooling fluid reservoir 232a extend into the lower cover 270 through interior spaces of the connecting members 273.

The gas supply unit 300 supplies a gas into the treatment space of the chamber 100. The gas supplied by the gas supply unit 300 includes a process gas that is used to treat the substrate W. Furthermore, the gas supply unit 300 may supply a cleaning gas that is used to clean the inside of the chamber 100.

The gas supply unit 300 includes a gas supply nozzle 310, a gas supply line 320, and a gas reservoir 330. The gas supply nozzle 310 is installed in the center of the cover 120. The gas supply nozzle 310 has an injection opening formed in the bottom thereof. The injection hole is located under the cover 120 and supplies the gas into the chamber 100. The gas supply line 320 connects the gas supply nozzle 310 and the gas reservoir 330. The gas supply line 320 is used to supply the gas stored in the gas reservoir 330 to the gas supply nozzle 310. A valve 321 is installed in the gas supply line 320. The valve 321 opens or closes the gas supply line 320 and adjusts the flow rate of the gas supplied through the gas supply line 320.

The plasma source 400 generates plasma from the gas supplied into the treatment space of the chamber 100. The plasma source 400 is provided outside the treatment space of the chamber 100. According to an embodiment, an inductively coupled plasma (ICP) source may be used as the plasma source 400. The plasma source 400 includes an antenna room 410, an antenna 420, and a plasma power supply 430. The antenna room 410 has a cylindrical shape that is open at the bottom. The antenna room 410 has a space therein. The antenna room 410 has a diameter corresponding to that of the chamber 100. A lower end of the antenna room 410 is provided so as to be detachable from the cover 120. The antenna 420 is disposed in the antenna room 410. The antenna 420 is implemented with a spiral coil wound a plurality of times and is connected with the plasma power supply 430. The antenna 420 receives power from the plasma power supply 430. The plasma power supply 430 may be located outside the chamber 100. The antenna 420 to which the power is applied may generate an electromagnetic field in the treatment space of the chamber 100. The process gas is excited into plasma by the electromagnetic field.

The exhaust unit 500 is located between the inner wall of the housing 110 and the support unit 200. The exhaust unit 500 includes an exhaust plate 510 having through-holes 511 formed therein. The exhaust plate 510 has an annular ring shape. The exhaust plate 510 has the through-holes 511 formed therein. The process gas supplied into the housing 110 passes through the through-holes 511 of the exhaust plate 510 and is released through the exhaust hole 102. The flow of the process gas may be controlled depending on the shape of the exhaust plate 500 and the shape of the through-holes 511.

Heaters 225 are embedded in the support plate 220. The heaters 225 are located under the electrostatic electrode 223. The heaters 225 may be provided in different regions in the support plate 220 to heat the support unit 200 for respective different regions of the substrate W.

A heater power supply 229 applies heating powers to the heaters 225. A filter 228 interrupts RF power from the heating powers supplied by the heater power supply 229. In a case where RF power of 13.56 MHz is applied by the plasma source 400 to generate plasma, the filter 228 may be designed to allow AC powers of 60 Hz to pass through heater cables 226a to 226d and interrupt introduction of the RF power of 13.56 MHz into the heater power supply 229. The filter 228 may be implemented with elements 228a to 228d such as a capacitor, an inductor, and the like.

The plurality of heater cables 226a to 226d are connected between the filter 228 and the heaters 255 and deliver the heating powers applied by the heater power supply 229 to the heaters 225. The heater cables 226a to 226d may extend into the lower cover 270 through the interior spaces of the connecting members 273. The heaters 225 are electrically connected with the heater cables 226a to 226d and generate heat by resisting the heating powers (currents) applied through the heater cables 226a and 226d. The generated heat is transferred to the substrate W through the support plate 220. The substrate W is maintained at a predetermined temperature by the heat generated from the heaters 225.

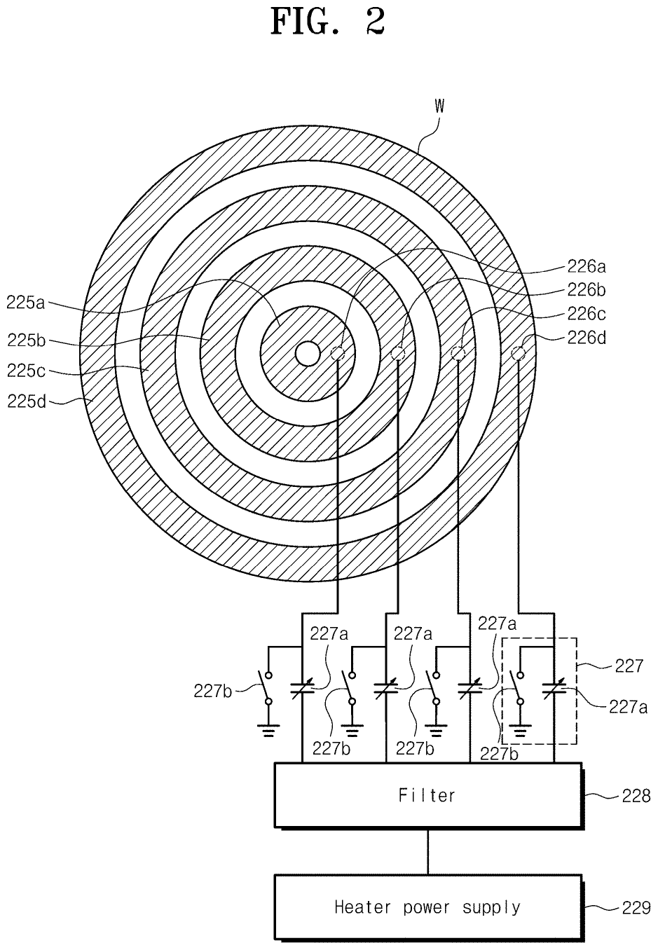

Variable capacitors 227 configured to be grounded may be connected to the plurality of heater cables 226a to 226d. The variable capacitors 227 configured to be grounded may adjust impedances of the plurality of heater cables 226a to 226d to adjust processing rates for the respective different regions of the substrate W. The processing rates may be etch rates. The variable capacitors 227 configured to be grounded will be described below in detail with reference to FIGS. 2 to 4.

FIG. 2 is a plan view illustrating the heaters 255, the heater cables 226a to 226d, the variable capacitors 227 configured to be grounded, the filter 228, and the heater power supply 229 constituting the substrate treating apparatus according to an embodiment of the inventive concept. Referring to FIG. 2, the variable capacitors 227 connected to ends of the heater cables 226a to 226d and configured to be grounded are illustrated. The heaters 225 may be disposed to be concentric with one another along the radial direction of the support plate 220 constituting the support unit 200. The heaters 225 may include a central heater 225a, the outermost heater 225d, and one or more intermediate heaters 225b and 225c between the central heater 225a and the outermost heater 225d. In the illustrated embodiment, the four heaters 225a to 225d are disposed to be concentric with one another. However, the number, shape, and arrangement structure of the heaters 255 may be diversely modified without being limited thereto. For example, the heaters 225 may be provided in a spiral coil shape. The heaters 255 may be provided in a quadrangular coil shape as well as a circular coil shape.

In the embodiment of FIG. 2, the variable capacitors 227 configured to be grounded may adjust impedances of the plurality of heater cables 226a to 226d to obtain a uniform processing rate in the radial direction of the substrate W. No special limitation applies to a method of measuring processing rates for respective regions of the substrate W. For example, the processing rates for the respective regions of the substrate W may be measured by a method of measuring etch depths by processing an image of a treated surface of the substrate W that is obtained by an image sensor, a method of locally measuring etch depths for the respective regions of the substrate W by interferometry end point detection (IEP) modules, or a method of predicting etch depths for the respective regions of the substrate W by measuring plasma density distribution by an optical emission spectrometer. However, the inventive concept is not limited thereto. The processing rates for the respective regions of the substrate W may be calculated in view of the arrangement structure of the heaters 225. For example, in a case where the heaters 255 are arranged in a concentric structure, the processing rates for the respective regions of the substrate W in the radial direction of the substrate W may be calculated.

The variable capacitors 227 connected with the plurality of heater cables 226a to 226d and configured to be grounded may decrease impedances of the heater cables 226a to 226d corresponding to regions having low processing rates among the regions of the substrate W and may increase impedances of the heater cables 226a to 226d corresponding to regions having high processing rates among the regions of the substrate W. For example, an etch rate of a region having a lower etch rate than the other regions of the substrate W in the radial direction may be increased by impedance decreased by a variable capacitor configured to be grounded. In contrast, an etch rate of a region having a higher etch rate than the other regions of the substrate W may be decreased by impedance increased by a variable capacitor configured to be grounded. Accordingly, an etch rate over the entire surface of the substrate W may be uniformly controlled. The outermost region of the substrate W may not exhibit uniform etch characteristics, compared with the central portion of the substrate W. However, according to this embodiment, an etch rate of the outermost region of the substrate W may be effectively controlled by adjusting impedance of a heater cable for the outermost region of the substrate W. Furthermore, because the heater cables 226a to 226b are connected close to the support unit 200 such as an electrostatic chuck, the heater cables 226a to 226d may affect impedances even in a case of a very small electrical change. Accordingly, a processing rate of the substrate W may be efficiently controlled.

The variable capacitors 227 configured to be grounded may uniformly control the processing rates in the radial direction of the substrate W by calculating the processing rates for the respective regions of the substrate W in the radial direction, decreasing impedance of a variable capacitor corresponding to a region having a low substrate processing rate, and increasing impedance of a variable capacitor corresponding to a region having a high substrate processing rate.

The variable capacitors 227 configured to be grounded may be connected to the plurality of heater cables 226a to 226 to adjust impedances of the heater cables 226a to 226d, respectively. The variable capacitors 227 configured to be grounded may be connected to the heater cables 226a to 226 to heat the heaters 225 connected to the heater cables 226a to 226d, respectively. According to an embodiment of the inventive concept, the variable capacitors 227 configured to be grounded may be connected to ends of the heater cables 226a to 226d. The variable capacitors 227 configured to be grounded may be connected to input terminals of the filter 228.

The variable capacitors 227 configured to be grounded refer to elements configured to perform a function of a ground while performing a function of a variable capacitor. Each of the variable capacitors 227 configured to be grounded may include a ground switch 227b connected with a variable capacitor 227a in parallel. In the inventive concept, a circuit of the variable capacitors 227 configured to be grounded according to an embodiment is illustrated. However, the scope of the inventive concept is not limited to that illustrated in the drawing. The configuration may be changed at the level of knowledge of a person skilled in the art.

The variable capacitors 227 configured to be grounded may include a configuration to connect the ground switch 227b in parallel and may adjust a ground state or a floating state. Alternatively, the ground state or the floating state may be adjusted by adjusting the distance between electrodes of the variable capacitor 227a or by inserting a material between the electrodes of the variable capacitor 227a.

Hereinafter, one embodiment of the variable capacitors 227 configured to be grounded and a configuration of a substrate treating apparatus using the same will be described.

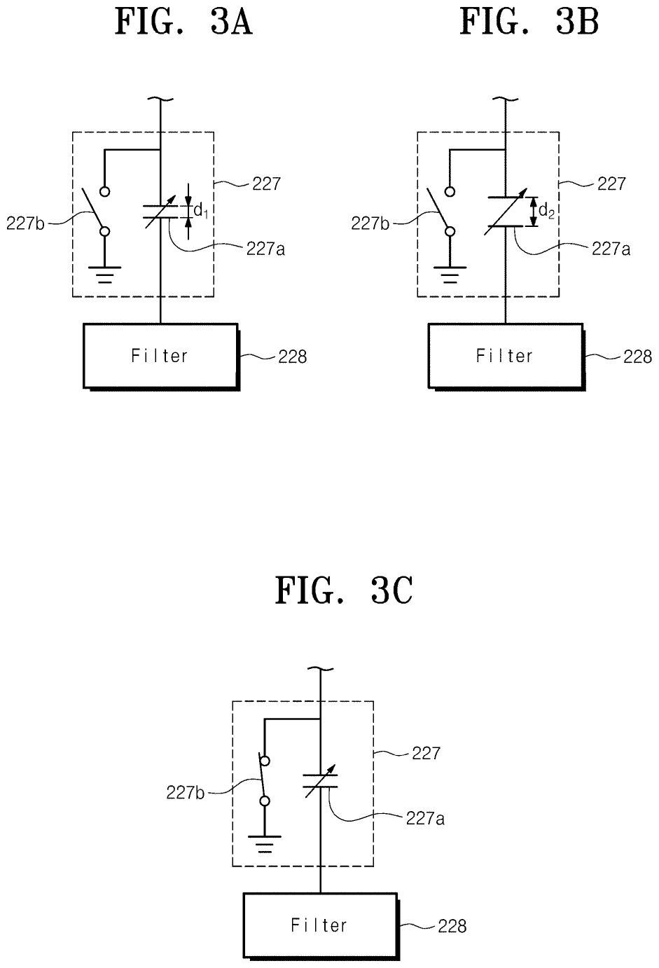

FIGS. 3A to 3C are views illustrating configurations of a variable capacitor connected with the filter 228 and configured to be grounded according to an embodiment of the inventive concept.

FIGS. 3A to 3C illustrate the variable capacitor 227 connected to one heater cable and configured to be grounded. However, the variable capacitor 227 configured to be grounded may be provided in the same number as that of heater cables.

FIGS. 3A to 3C illustrate examples that the variable capacitor 227 configured to be grounded according to the inventive concept is diversely changed to operate in a ground state or a floating state.

FIGS. 3A and 3B illustrate examples that the variable capacitor 227 configured to be grounded operates in a floating state.

Referring to FIG. 3A, in the variable capacitor 227 configured to be grounded, the ground switch 227b may be turned off, and impedance of the heater cable may be adjusted depending on the capacity of the variable capacitor 227a. The distance between electrodes in the variable capacitor may be adjusted to d1.

Referring to FIG. 3B, in the variable capacitor 227 configured to be grounded, the ground switch 227b may be turned off, and impedance of the heater cable may be adjusted depending on the capacity of the variable capacitor 227a. The distance between the electrodes in the variable capacitor may be adjusted to d2.

Referring to FIGS. 3A and 3B, the floating state may be maintained by turning off the ground switch 227b in the variable capacitor 227 configured to be grounded and adjusting the distance between the electrodes in the variable capacitor 227a. Furthermore, in the floating state, plasma voltages applied to respective different regions of the substrate W may be adjusted by freely adjusting impedance by adjusting the distance between the electrodes in the variable capacitor 227a.

FIG. 3C illustrates one example that the variable capacitor 227 configured to be grounded operates in a ground state.

Referring to FIG. 3C, the heater connected with the corresponding heater cable may be grounded by turning on the ground switch 227b in the variable capacitor 227 configured to be grounded. In a case where the variable capacitor 227 configured to be grounded is grounded by turning on the ground switch 227b, power loss may occur in the corresponding heater cable through the ground. In the ground state of the variable capacitor 227 configured to be grounded, RF power loss may occur through the cable, and etch rates for the respective different regions of the substrate W may be controlled to be decreased. Accordingly, process results for the respective different regions of the substrate W may be controlled.

Referring to FIGS. 3A to 3C, plasma voltage and an etch rate may be varied depending on the ground state or the floating state of the variable capacitor 227 configured to be grounded. In the case of the ground state, plasma power loss may occur along the heater cables connected with the different regions of the substrate W. In a case where the heater cable connected with each of the regions of the substrate W is in a ground state, an etch rate is decreased depending on plasma power loss in the corresponding region. The etch rate may be controlled by adjusting the ground state in the heater cable connected with the corresponding region.

In contrast, in the case of the floating state, the heater cables connected with the different regions of the substrate W are connected with the filter, and therefore plasma power loss does not occur. Accordingly, impedances of the heater cables may be adjusted without RF power loss. That is, by connecting the variable capacitors configured to be grounded to the heater cables connected with the different regions of the substrate W, etch rates for respective zones may be adjusted through various methods.

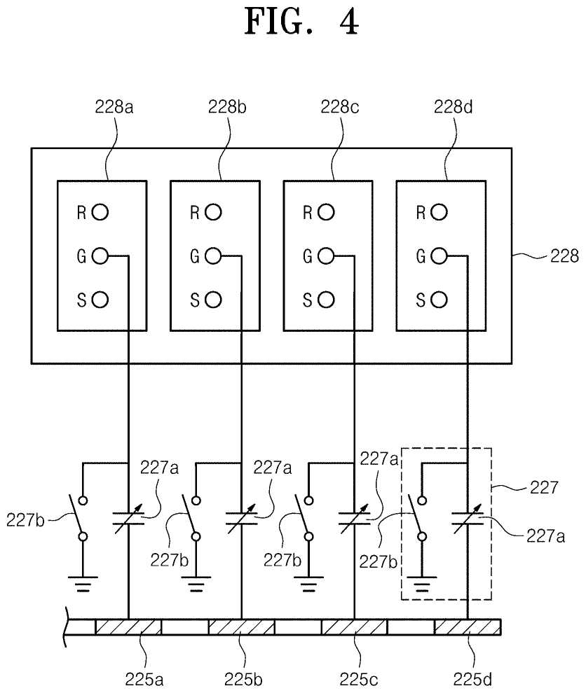

FIG. 4 is a view illustrating connection of terminals of the filter 228 and the variable capacitors 227 configured to be grounded, according to the inventive concept.

Referring to FIG. 4, the filter 228 may include the first to fourth filers 228a to 228d individually connected with the respective different regions of the substrate W. The first filter 228a may be connected with the central heater 225a for the substrate W. The second filter 228b may be connected with the intermediate heater 225b for the substrate W. The third filter 228c may be connected with the intermediate heater 225c for the substrate W. The fourth filter 228d may be connected with the outermost heater 225d for the substrate W. The filters 228a to 228d and the heaters 225a to 225d may be connected through the corresponding heater cables 226a to 226d, and the variable capacitors 277 configured to be ground may be connected to the heater cables 226a to 226d.

As illustrated in FIG. 4, each of the first to fourth filters 228a to 228d may include a plurality of terminals. One of the terminals included in each filter may be a ground terminal. The ground terminal may be denoted by “G”.

When the heater cables 226a to 226d are connected to the ground terminals G included in the filters 228a to 228d, the heater cables 226a to 226d may be grounded. When the heater cables 226a to 226d are connected to the remaining terminals R or S other than the ground terminals G included in the filters 228a to 228d, power may be applied from the heater power supply 229.

In the inventive concept, etch rates may be controlled by adjusting ground or floating states at the ground terminals G by connecting the variable capacitors 227 configured to be grounded to the heater cables 226a to 226d connected with the ground terminals G.

In FIG. 4, the heater cables 226a to 226d are illustrated as being connected with the heaters 225a to 225b included in the different regions of the substrate W, respectively. However, a plurality of cables may be connected with each of the heaters 225a to 225d included in the different regions of the substrate W.

The substrate treating apparatus according to the inventive concept may switch between ground states and floating states of the variable capacitors 227 that are configured to be grounded and are connected to the heater cables 226a to 226d connected with the ground terminals G. The substrate treating apparatus according to the inventive concept may switch between the ground states and the floating states of the variable capacitors 227 configured to be grounded and may improve process deviations for the respective different regions of the substrate W by adjusting the distances between the electrodes of the variable capacitors 227a in the floating states.

Although not illustrated in the drawings of the inventive concept, a controller for controlling the variable capacitors 227, which are connected to the heater cables 226a to 226d and are configured to be grounded, by using measured plasma voltage values may be further included in the substrate treating apparatus according to the inventive concept.

The controller may select a region of the substrate W for which plasma voltage is to be adjusted, by using plasma voltages measured for the respective different regions of the substrate W. When the region of the substrate W for which the plasma voltage is to be adjusted is selected, the controller may control the variable capacitor 227 that is configured to be grounded and is connected with the selected region.

The controller may adjust the capacity of the variable capacitor 227a included in the variable capacitor 227 that is configured to be grounded and is connected with the heater cable connected with the selected region. Alternatively, the controller may perform control to turn on/off the ground switch 227b in the variable capacitor 227 that is configured to be grounded and is connected with the heater cable connected with the selected region. The controller may adjust the plasma voltage as much as desired, by adjusting the distance between the electrodes included in the variable capacitor 227a or by turning on/off the ground switch 227b.

The substrate treating apparatus according to the inventive concept may further include a sensor for measuring plasma voltages for the respective different regions of the substrate W. The sensor may be installed in the chamber 100. The sensor may measure plasma voltages for the respective different regions of the substrate W and may transfer the measured plasma voltages to the controller. A plurality of sensors may be provided.

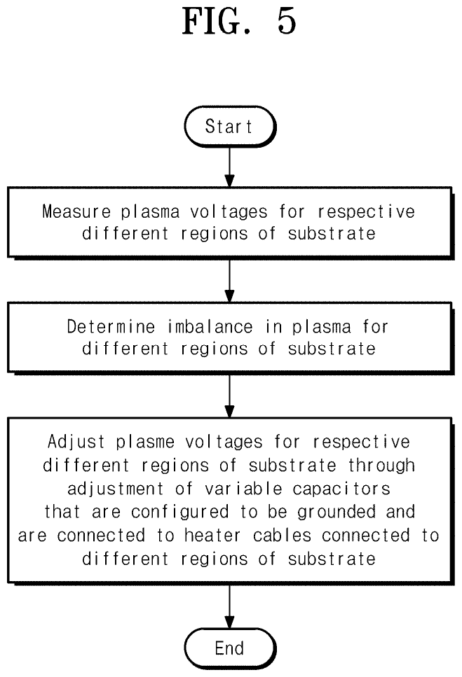

FIG. 5 is a flowchart illustrating a substrate treating method according to the inventive concept.

A system for controlling temperatures for respective different regions of a substrate may be provided in a substrate treating apparatus according to the inventive concept. To control the temperatures for the respective different regions of the substrate, a configuration in which heater cables are connected to multiple zones of the substrate is disclosed. Depending on whether one end of each heater cable is grounded or floated, the voltage of plasma sheath for a portion connected with the heater cable may be affected. The voltage change may cause a change in an etch rate and a process result.

To control this, in the inventive concept, a variable capacitor configured to be grounded is connected to the one end of the heater cable to allow the heater cable to operate in one of a ground state or a floating state, thereby adjusting the voltage of the plasma sheath and thus improving etch uniformity. In addition, an improvement in a process result deviation may be obtained.

In the inventive concept, plasma voltages for the respective different regions of the substrate are measured. The plasma voltages may be measured through a sensor provided in a chamber. Parameters measured for the respective different regions of the substrate are not limited to the plasma voltages and may be parameters, such as etch rates, which are associated with plasma.

An imbalance in plasma for the different regions of the substrate is determined through the results of the parameters obtained in the above step. The imbalance in plasma may be derived through etch rates or plasma voltages.

Through the above step, a region to be adjusted among the different regions of the substrate may be selected. Thereafter, plasma voltage may be adjusted by controlling a variable capacitor that is configured to be grounded and is included in a cable connecting the region to be adjusted and a heater power supply.

In the inventive concept, variable capacitors configured to be grounded may operate in one of a ground state or a floating state. In the inventive concept, in a case where plasma voltages need to be adjusted, the variable capacitors configured to be grounded may operate in the floating state. Accordingly, plasma voltages for the respective different regions of the substrate may be adjusted by adjusting impedances of the heater cables. In the inventive concept, in a case where there is a difference in etch rate between the different regions of the substrate, a variable capacitor that is configured to be grounded and is connected to a heater cable connected with a region of the substrate that has a high etch rate may operate in the ground state. Accordingly, an etch rate and an etch amount may be uniformly adjusted.

In the inventive concept, plasma voltages applied to the respective different regions of the substrate may be controlled by allowing the variable capacitors configured to be grounded to operate in the floating state. In the inventive concept, power losses for the respective different regions of the substrate may be adjusted by allowing the variable capacitors configured to be grounded to operate in the ground state. Through the adjustment of the ground state, power loss of the substrate may be adjusted.

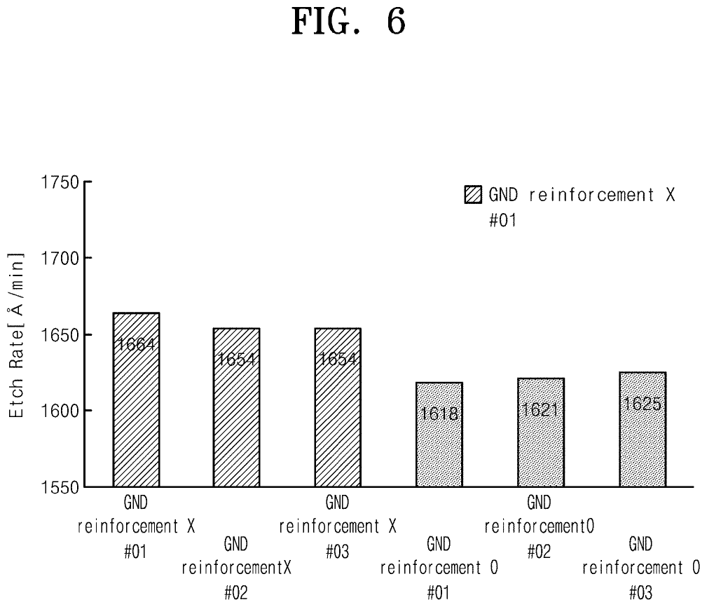

FIG. 6 is a view illustrating a difference in etch rate between an existing substrate treating apparatus and a substrate treating apparatus according to the inventive concept. FIG. 6 is a graph depicting an etch rate in a case where an end of a heater cable is not grounded and an etch rate in a case where the end of the heater cable is grounded.

The vertical axis in the graph of FIG. 6 represents an etch rate. The etch rate refers to an etching velocity. The etch rate may mean the degree to which a film is removed for a predetermined period of time and may be changed depending on the amounts of radical atoms and ions required for a surface reaction and energies of ions.

The horizontal axis in the graph of FIG. 6 represents heater cables. The first three parameters on the horizontal axis in the graph of FIG. 6 represent cases where ends of heater cables are not grounded, and the last three parameters on the horizontal axis in the graph of FIG. 6 represent cases where etch rates are measured while variable capacitors configured to be grounded according to the inventive concept are connected to ends of heater cables.

According to the graph of FIG. 6, it can be seen that the etch rates range between 1650 Å/min and 1664 Å/min in the case where the ends of the heater cables are not grounded. Furthermore, it can be seen that the etch rates range between 1618 Å/min and 1625 Å/min in the case where the ends of the heater cables are connected to the variable capacitors configured to be grounded. That is, it can be seen that in the case of making an adjustment by connecting the variable capacitors configured to be grounded, etch rates are adjusted by freely adjusting a ground.

As described above, according to the inventive concept, plasma voltages may be improved and controlled in desired directions by using the variable capacitors that are configured to be grounded and are connected to ends of the cables.

According to the inventive concept, the voltage of plasma sheath may be controlled by allowing the variable capacitors, which are configured to be grounded and are connected to the ends of the cables, to operate in the ground state or the floating state.

According to the inventive concept, power losses may be adjusted by adjusting the variable capacitors configured to be grounded.

Effects of the inventive concept are not limited to the above-described effects. Any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a chamber having a treatment space therein;
a support unit configured to support the substrate in the treatment space;
a gas supply unit configured to supply, into the treatment space, a process gas used to treat the substrate;
a plasma source configured to generate plasma by exciting the process gas supplied into the treatment space;
heaters configured to heat the support unit for different regions of the substrate;
a heater power supply configured to apply powers to the heaters;
a plurality of heater cables configured to deliver the powers to the heaters; and
variable capacitors configured to be grounded, the variable capacitors being connected to the plurality of heater cables, respectively.

2. The apparatus of claim 1, further comprising:
a filter configured to pass the powers through the plurality of heater cables and interrupt introduction of RF power into the heater power supply,
wherein the plurality of heater cables are connected between the filter and the heaters.

3. The apparatus of claim 2, wherein the variable capacitors configured to be grounded are connected to input terminals of the filter.

4. The apparatus of claim 3, wherein the filter includes a plurality of terminals, and
wherein the variable capacitors configured to be grounded are connected to ground terminals among the plurality of terminals.

5. The apparatus of claim 4, wherein the variable capacitors configured to be grounded operate in one of a ground state or a floating state.

6. The apparatus of claim 5, wherein in the floating state, plasma voltages applied to the respective different regions of the substrate are controlled by adjusting a distance between electrodes of each of the variable capacitors.

7. The apparatus of claim 5, wherein the ground state is adjusted by turning on/off a ground switch connected in parallel with each of the variable capacitors.

8. The apparatus of claim 5, wherein the apparatus adjusts magnitudes of power losses for the respective different regions of the substrate by adjusting the variable capacitors configured to be grounded.

9. The apparatus of claim 5, wherein the apparatus adjusts plasma voltages applied to the respective different regions of the substrate by adjusting the variable capacitors configured to be grounded.

10.-19. (canceled)
